(19) United States
(12) Patent Application Publication
(10) Pub. No.: US 2025/0093768 A1
(43) Pub. Date: Mar. 20, 2025

(54) CONTROL DEVICE AND SUBSTRATE PROCESSING APPARATUS INCLUDING THE SAME

(71) Applicants: SEMES CO., LTD., Cheonan-si (KR); SAMSUNG ELECTRONICS CO. LTD., Suwon-si (KR)

(72) Inventors: Jin Yeong SUNG, Gyeonggi-do (KR); Ki Hoon CHOI, Chungcheongnam-do (KR); Seung Un OH, Chungcheongnam-do (KR); Young Ho PARK, Incheon (KR); Sang Hyeon RYU, Gyeonggi-do (KR); Jang Jin LEE, Seoul (KR); Hyun YOON, Seoul (KR); Sang Gun LEE, Seoul (KR); Yu Jin CHO, Gyeonggi-do (KR); Ho Jong HWANG, Gyeonggi-do (KR); Jong Ju PARK, Suwon-si (KR); Jong Keun OH, Suwon-si (KR); Yong Woo KIM, Suwon-si (KR)

(73) Assignees: SEMES CO., LTD., Cheonan-si (KR); SAMSUNG ELECTRONICS CO. LTD., Suwon-si (KR)

(21) Appl. No.: 18/770,090

(22) Filed: Jul. 11, 2024

(30) Foreign Application Priority Data
Sep. 19, 2023 (KR) 10-2023-0124463

(51) Int. Cl. G03F 1/72; G03F 1/84; G06T 7/20; G06T 7/66

(52) U.S. Cl. CPC G03F 1/72; G03F 1/84; G06T 7/20; G06T 7/66; G06T 2207/30241

(57) ABSTRACT

A substrate processing apparatus is provided and includes: a support unit including a spin chuck and a centering jig that is on the spin chuck, the spin chuck configured to support and rotate a substrate; a spraying unit configured to spray processing liquid onto the substrate; a swing arm including a correction unit that includes a sensor and an emitter, the swing arm configured to move such that the correction unit moves to a target point on the substrate, and the emitter configured to irradiate a beam towards the substrate; and a controller configured to: control the spin chuck and the swing arm; and determine whether a movement trajectory of the swing arm is aligned with a rotation center of the spin chuck based on information acquired by the sensor about the centering jig.

### CROSS-REFERENCE TO RELATED APPLICATION

This application claims priority from Korean Patent Application No. 10-2023-0124463, filed on Sep. 19, 2023, in the Korean Intellectual Property Office, and all the benefits accruing therefrom under 35 U.S.C. 119, the entire contents of which are herein incorporated by reference.

### BACKGROUND

### 1. Field

Embodiments of the present disclosure relate to a centering method applied to equipment for correcting the critical dimension of a mask or a reticle, a computer program for executing the centering method, a control device equipped with a processor for running the computer program, and a substrate processing apparatus including the control device.

### 2. Description of Related Art

In a photolithography process, a photomask can be used to form circuit patterns on semiconductor devices. To produce semiconductor devices with high precision and uniformity, the pattern linewidth of the semiconductor devices can be identified, and the critical dimension (CD) of the photomask can be corrected.

Equipment for correcting the CD of a mask may utilize a swing stage equipped with a swing arm and a spin chuck due to spatial issues within a chamber and contamination risks. However, if the movement trajectory of the swing arm does not pass through the rotation center of the spin chuck, a non-etchable dead zone may occur on the mask.

### SUMMARY

According to embodiments of the present disclosure, a control device capable of allowing the movement trajectory of a swing arm to pass through the rotation center of a spin chuck with the use of a centering jig may be provided, and a substrate processing apparatus including the control device may be provided.

According to embodiments of the present disclosure, a substrate processing apparatus is provided and includes: a support unit including a spin chuck and a centering jig that is on the spin chuck, the spin chuck configured to support and rotate a substrate; a spraying unit configured to spray processing liquid onto the substrate; a swing arm including a correction unit that includes a sensor and an emitter, the swing arm configured to move such that the correction unit moves to a target point on the substrate, and the emitter configured to irradiate a beam towards the substrate; and a controller configured to: control the spin chuck and the swing arm; and determine whether a movement trajectory of the swing arm is aligned with a rotation center of the spin chuck based on information acquired by the sensor about the centering jig.

According to embodiments of the present disclosure, a control device is provided and includes a controller configured to: control a spin chuck, that is configured to support and rotate a substrate, and a swing arm, that is configured to move to a target point on the substrate and irradiate a beam for processing the substrate; and determine whether a movement trajectory of the swing arm is aligned with a rotation center of the spin chuck by processing a plurality of images obtained by the swing arm, the plurality of images including a first hole of a centering jig at the rotation center of the spin chuck, wherein the centering jig is on the spin chuck.

According to embodiments of the present disclosure, a substrate processing apparatus is provided and includes: a support unit including a spin chuck and a centering jig that is on the spin chuck, the spin chuck configured to support and rotate a substrate; a spraying unit configured to spray processing fluid onto the substrate; a swing arm including a correction unit that includes a sensor and an emitter, the swing arm configured to move such that the correction unit moves to a target point on the substrate, and the correction unit configured to irradiate a beam, via the emitter, towards the substrate and acquire a plurality of images, via the sensor, while the spin chuck is rotated a predetermined angle; and a controller configured to: control the spin chuck and the swing arm; rescale each of the plurality of images based on brightness; extract enlarged images of a first hole by binarizing the plurality of images, that are rescaled, using a threshold; calculate a center-of-mass position of the first hole from each of the enlarged images that are extracted; perform circle fitting on the center-of-mass position of the first hole; and determine whether a movement trajectory of the swing arm passes through a rotation center of the spin chuck based on a result of the circle fitting.

However, aspects and effects of embodiments of the present disclosure are not restricted to those set forth herein. The above and other aspects and effects of embodiments of the present disclosure will become more apparent to one of ordinary skill in the art to which the present disclosure pertains by referencing the detailed description of the present disclosure given below.

### BRIEF DESCRIPTION OF DRAWINGS

The above and other aspects of embodiments of the present disclosure will become more apparent by describing in detail non-limiting example embodiments thereof with reference to the attached drawings, in which:

FIG. 1 is a block diagram illustrating an internal configuration of a substrate processing apparatus;

FIG. 2 is a first example schematic diagram for explaining the internal configuration of the substrate processing apparatus;

FIG. 3 is a second example schematic diagram for explaining the internal configuration of the substrate processing apparatus;

FIG. 4 is an example schematic diagram for explaining an internal configuration of a correction unit within the substrate processing apparatus;

FIG. 5 is a first example schematic diagram for explaining a role of a centering jig in the substrate processing apparatus;

FIG. 6 is a second example schematic diagram for explaining a role of the centering jig in the substrate processing apparatus;

FIG. 7 is a plan view for explaining a structure of a centering jig according to a first embodiment of the present disclosure;

FIG. 8 is a flowchart for explaining a method of aligning a movement trajectory of a swing arm with a rotation center of a spin chuck;

FIG. 9 is a flowchart for explaining a method of processing multiple images;

FIG. 10 is an example schematic diagram for explaining circle fitting as performed in the method of FIG. 9;

FIG. 11 is a flowchart for explaining a method of measuring a length of the swing arm;

FIG. 12 is an example schematic diagram for explaining the method of FIG. 11;

FIG. 13 is a side view for explaining a structure of a centering jig according to a second embodiment of the present disclosure;

FIG. 14 is a plan view for explaining the structure of the centering jig according to the second embodiment of the present disclosure;

FIG. 15 is a side view for explaining a structure of a centering jig according to a third embodiment of the present disclosure; and

FIG. 16 is a side view for explaining a structure of a centering jig according to a fourth embodiment of the present disclosure.

### DETAILED DESCRIPTION

Non-limiting example embodiments of the present disclosure will be described with reference to the attached drawings. The same reference numerals are used for the same components in the drawings, and redundant descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

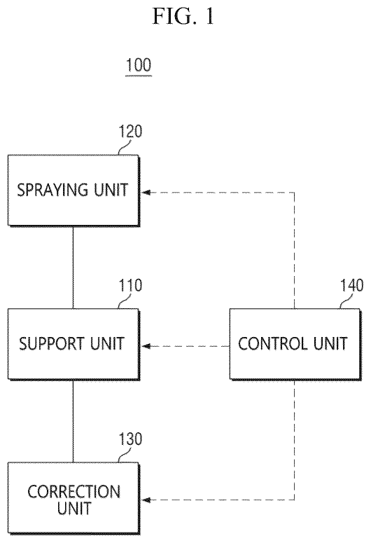

FIG. 1 is a block diagram illustrating an internal configuration of a substrate processing apparatus. Referring to FIG. 1, a substrate processing apparatus 100 may include a support unit 110 (e.g., a support), a spraying unit 120, a correction unit 130, and a control unit 140 (e.g., a controller).

The substrate processing apparatus 100 may perform a wet etching process on a substrate. Alternatively, the substrate processing apparatus 100 may perform a wet cleaning process on a substrate. The substrate processing apparatus 100 may be applicable to a photolithography process.

The substrate processing apparatus 100 may correct the critical dimension (CD) of a substrate using a beam. For example, the substrate processing apparatus 100 may use an extreme ultraviolet (EUV) beam to correct CD. For example, the substrate processing apparatus 100 may correct the CD of a photomask or a reticle.

The support unit 110 may support a substrate when processing the substrate. The support unit 110 may support a substrate when spraying chemicals on the substrate. The support unit 110 may support a substrate when correcting the CD of the substrate using a beam.

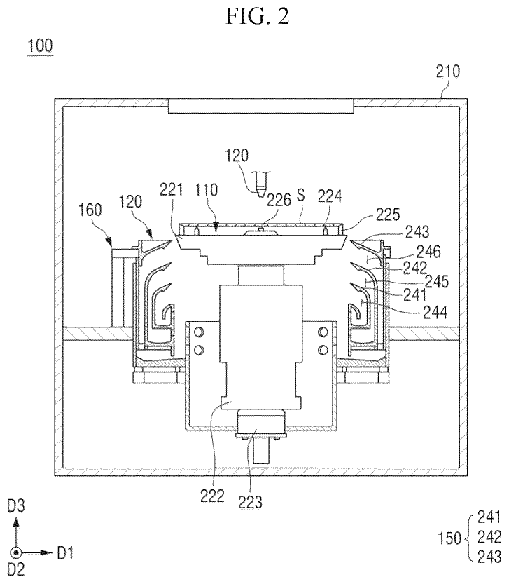

The support unit 110 may be provided as a swing-type stage. The support unit 110 may include a spin chuck or a rotation chuck. For example, with reference to FIG. 2, the support unit 110 may include a spin chuck 221, a rotating shaft 222, a rotation drive part 223, support pins 224, and guide pins 225.

FIG. 2 is a first example schematic diagram for explaining the internal configuration of the substrate processing apparatus.

Referring to FIG. 2, a first direction D1 and a second direction D2 are within a plane (e.g., a horizontal plane). For example, the first direction D1 may be a front-rear direction, and the second direction D2 may be a left-right direction. Alternatively, the first direction D1 may be the left-right direction, and the second direction D2 may be the front-rear direction. A third direction D3 is a height direction and is perpendicular to the first direction D1 and the second direction D2. The third direction D3 may be a top-down direction.

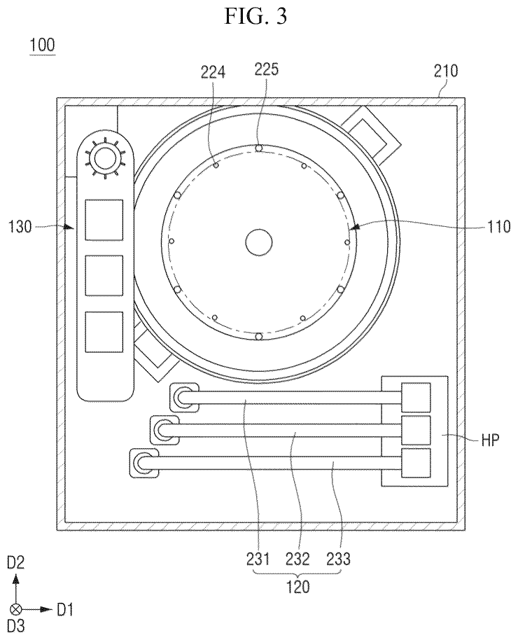

The support unit 110 may be provided within a chamber housing 210. With reference to FIG. 3, the spraying unit 120 and the correction unit 130 may be provided on the chamber housing 210. The chamber housing 210 may provide space for processing a substrate S. However, embodiments of the present disclosure are not limited to this. Alternatively, the support unit 110, the spraying unit 120, and the correction unit 130 may all be provided within the chamber housing 210.

The spin chuck 221 may be provided to accommodate the substrate S thereon. The spin chuck 221 may rotate according to the operation of the rotating shaft 222. The substrate S may rotate together with the spin chuck 221 while being seated on the spin chuck 221. The spin chuck 221 may rotate clockwise. Alternatively, the spin chuck 221 may rotate counterclockwise.

A planar shape of the spin chuck 221 may be different from a planar shape of the substrate S. For example, the spin chuck 221 may be formed as a cylinder and may have a circular planar shape, while the substrate S may have a rectangular planar shape. However, embodiments of the present disclosure are not limited to this example. Alternatively, the spin chuck 221 and the substrate S may have a same planar shape as each other.

The rotating shaft 222 may generate rotational force using the electrical energy provided from the rotation drive part 223. The rotating shaft 222 may provide rotational force to the spin chuck 221 to rotate the spin chuck 221.

The support pins 224 and the guide pins 225 may be provided on the spin chuck 221 to support the substrate S. The support pins 224 may support the bottom surface of the substrate S so that the substrate S may not contact the top surface of the spin chuck 221. The guide pins 225 may support the side of the substrate S to fix the position of the substrate S on the spin chuck 221. The guide pins 225 may function as chucking pins. The guide pins 225 may support the side of the substrate S to prevent the substrate S from being detached from the spin chuck 221 when the spin chuck 221 rotates.

The support pins 224 and the guide pins 225 may be provide in an upper edge area of the spin chuck 221. A plurality of support pins 224 and a plurality of guide pins 225 may be provided on the spin chuck 221, but embodiments of the present disclosure are not limited thereto. The support pins 224 and the guide pins 225 may be disposed to have an annular ring shape.

A centering jig 226 for aligning the rotation center of the spin chuck 221 with the movement trajectory of the swing arm 250 may be provided. The centering jig 226 enables the movement trajectory of the swing arm 250 to pass through the rotation center of the spin chuck 221. The centering jig 226 may be provided in an upper central area of the spin chuck 221. The swing arm 250 and the centering jig 226 will be described later in further detail.

Referring back to FIG. 1, the spraying unit 120 sprays a processing liquid onto the substrate S. The spraying unit 120 may include a plurality of nozzles, but embodiments of the present disclosure are not limited thereto. Alternatively, the spraying unit 120 may include a single nozzle. In a case where the spraying unit 120 includes a plurality of nozzles, the nozzles may spray different processing liquids. For example, with reference to FIG. 3, the spraying unit 120 may include a first nozzle 231, a second nozzle 232, and a third nozzle 233.

FIG. 3 is a second example schematic diagram for explaining the internal configuration of the substrate processing apparatus.

Referring to FIG. 3, the first nozzle 231, the second nozzle 232, and the third nozzle 233 may move to a process position or a home port HP. The process position refers to an upper area of the substrate S. After moving to the process position, the first nozzle 231, the second nozzle 232, and the third nozzle 233 may spray processing liquids onto the substrate S. The home port HP is disposed in an outer area beyond the top of the substrate S. After spraying the processing liquids on the substrate S, the first nozzle 231, the second nozzle 232, and the third nozzle 233 may move to the home port HP to wait.

The first nozzle 231, the second nozzle 232, and the third nozzle 233 may rotate to move from the process position to the home port HP. After rotating, the first nozzle 231, the second nozzle 232, and the third nozzle 233 may elevate at the home port HP. The first nozzle 231, the second nozzle 232, and the third nozzle 233 may elevate at the process position and then rotate.

The first nozzle 231, the second nozzle 232, and the third nozzle 233 may rotate to move from the home port HP to the process position. After rotating, the first nozzle 231, the second nozzle 232, and the third nozzle 233 may elevate at the process position. The first nozzle 231, the second nozzle 232, and the third nozzle 233 may elevate at the home port HP and then rotate.

The first nozzle 231 may spray a first processing liquid. The second nozzle 232 may spray a second processing liquid. The third nozzle 233 may spray a third processing liquid. The first, second, and third processing liquids may contain the same material as each other. Alternatively, the first, second, and third processing liquids may contain different materials from each other. Alternatively, some of the first, second, and third processing liquids may contain the same material, and the rest may contain a different material.

The first processing liquid may be an alkaline solution. For example, the first nozzle 231 may spray Standard Cleaning 1 (SC-1). The SC-1 may be a hydrogenous solution containing hydrogen peroxide (H₂O₂) and ammonium hydroxide (NH₄OH). The second processing liquid may be a hydrogenous solution diluted with an alkaline chemical. For example, the second nozzle 232 may spray hydrogen water (H₂W). The first and second processing liquids may be provided simultaneously on the substrate S, but embodiments of the present disclosure are not limited thereto. Alternatively, the first and second processing liquids may be sequentially provided on the substrate S. The third processing liquid may be a rinse liquid. For example, the third nozzle 233 may spray deionized water (DIW).

According to embodiments, with reference to FIG. 2, the substrate processing apparatus 100 may further include a collection unit 150 and an elevation unit 160.

Referring to FIG. 2, the collection unit 150 may be provided to surround the support unit 110. The collection unit 150 may collect the processing liquids used in processing or treating the substrate S. When the substrate S is fixed on the support unit 110 and the support unit 110 rotates, the spraying unit 120 may spray the processing liquids onto the substrate S. The processing liquids discharged onto the substrate S may be flung toward the direction where the collection unit 150 is located, due to the centrifugal force generated by the rotation of the support unit 110. The collection unit 150 may collect the processing liquids scattered in all directions, through inlets.

The collection unit 150 may be configured to include a plurality of collection ducts. The collection unit 150 may collect different types of processing liquids into different collection ducts, enabling the reuse of the processing liquids. For example, the collection unit 150 may include a first collection duct 241, a second collection duct 242, and a third collection duct 243. The first collection duct 241, the second collection duct 242, and the third collection duct 243 may have a bowl shape.

The first collection duct 241, the second collection duct 242, and the third collection duct 243 may collect different types of processing liquids. For example, the first collection duct 241 may collect the third processing liquid, the second collection duct 242 may collect the first processing liquid, and the third collection duct 243 may collect the second processing liquid. The first collection duct 241 may collect the third processing liquid through a first inlet 244. The second collection duct 242 may collect the first processing liquid through a second inlet 245. The third collection duct 243 may collect the second processing liquid through a third inlet 246.

According to embodiments of the present disclosure, the first collection duct 241, the second collection duct 242, and the third collection duct 243 may be connected to respective recovery lines. The processing liquids collected through the first collection duct 241, the second collection duct 242, and the third collection duct 243 may be made reusable through a processing liquid regeneration unit.

The first collection duct 241, the second collection duct 242, and the third collection duct 243 may be provided in an annular ring shape. The first collection duct 241 may be installed to surround the support unit 110. The second collection duct 242 may be installed to surround the first collection duct 241. The third collection duct 243 may be installed to surround the second collection duct 242.

Meanwhile, if the spraying unit 120 includes a single nozzle, the collection unit 150 may include a single collection duct. The collection unit 150 may be equipped with as many collection ducts as there are nozzles in the spraying unit 120.

The elevation unit 160 may lift the collection unit 150. The elevation unit 160 may simultaneously lift the first collection duct 241, the second collection duct 242, and the third collection duct 243. Depending on the types of the processing liquids, the elevation unit 160 may adjust the height of the collection unit 150 so that the processing liquids may be collected into the respective collection ducts (e.g., the first collection duct 241, the second collection duct 242, and the third collection duct 243) through the respective inlets (e.g., the first inlet 244, the second inlet 245, and the third inlet 246). According to embodiments of the present disclosure, the elevation unit 160 may include at least one actuator that is configured to lift the collection unit 150.

Referring back to FIG. 1, the correction unit 130 may correct information related to pattern elements formed on the substrate S, using a beam. For example, the correction unit 130 may correct the CD of the pattern elements using a laser beam. A mask will hereinafter be described as being an example of the substrate S, but embodiments of the present disclosure are not limited thereto. Alternatively, in another example, the substrate S may be a reticle.

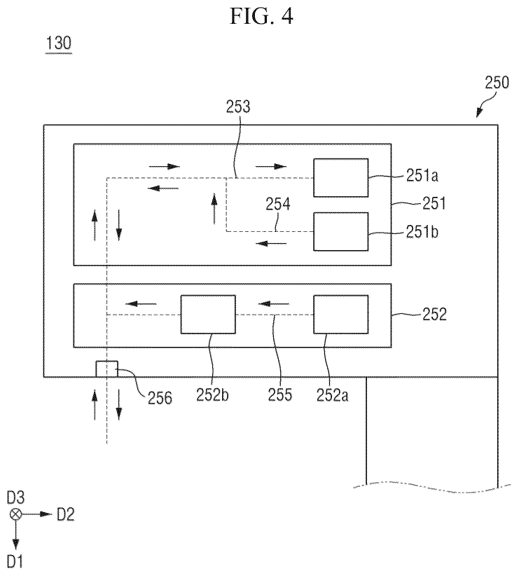

With reference to FIG. 4, the correction unit 130 may include an image acquisition module 251 and a beam irradiation module 252 to correct the CD of pattern elements formed on the mask. The image acquisition module 251 and the beam irradiation module 252 may be mounted within a swing arm 250.

FIG. 4 is an example schematic diagram for explaining an internal configuration of the correction unit within the substrate processing apparatus.

The image acquisition module 251 may acquire a surface image of the mask. The surface image of the mask may include the shape of patterns formed on the mask. Using the surface image of the mask, the linewidth of the patterns formed on the mask can be identified.

The image acquisition module 251 may be configured as a vision system that includes a vision camera. The image acquisition module 251 may include a camera sensor 251a and a lamp 251b. The lamp 251b may illuminate the surface of the mask along a second optical path 254. The lamp 251b may be provided as, for example, a light-emitting diode (LED) lamp. The camera sensor 251a may acquire the surface image of the mask while the lamp 251b is operating. The camera sensor 251a may acquire the surface image of the mask based on an optical signal that enters through a light inlet 256 and travels along a first optical path 253. According to embodiments of the present disclosure, the image acquisition module 251 may further include lenses, mirrors, etc., along the first optical path 253 and the second optical path 254.

The beam irradiation module 252 may irradiate a laser beam onto the surface of the mask. The beam irradiation module 252 may irradiate the laser beam onto the mask when a processing liquid is provided on the mask. The beam irradiation module 252 may irradiate the laser beam along a third optical path 255.

The beam irradiation module 252 may locally heat a designated location on the mask based on information provided by the surface image of the mask. The laser beam may activate the processing liquid on the mask, potentially increasing the efficiency of etching or cleaning the mask. The beam irradiation module 252 may adjust the linewidth of the micro-patterns formed on the mask.

The beam irradiation module 252 may be provided as a laser optic module that includes a laser source. The beam irradiation module 252 may include a laser sensor 252a and a beam expander 252b. Additionally, according to embodiments of the present disclosure, the beam irradiation module 252 may further include a beam splitter, mirrors, etc., along the third optical path 255.

Referring back to FIG. 1, the control unit 140 may control the overall operations of the support unit 110, the spraying unit 120, and the correction unit 130. Furthermore, the control unit 140 may also control the overall operations of the collection unit 150 and the elevation unit 160.

The control unit 140 may include a processor that executes control over each of the components of the substrate processing apparatus 100, a network that facilitates wired or wireless communication with each of the components of the substrate processing apparatus 100, and a storage means that stores instructions related to functions or operations for controlling each of the components of the substrate processing apparatus 100, processing recipes including instructions, various data, etc. Additionally, the control unit 140 may further include a user interface that includes an input means for an operator to manage the substrate processing apparatus 100 through command input operations and output means to visualize and display the operating status of the substrate processing apparatus 100. The control unit 140 may be provided as a computing device for data processing and analysis, command transmission, etc.

The instructions may be provided in the form of a computer program or application. The computer program may include one or more instructions and may be stored on a computer-readable recording medium. The instructions may encompass code generated by a compiler, code executable by an interpreter, etc. The storage means may be provided as one or more storage media selected from among a hard disk drive (HDD), a solid-state drive (SSD), a card-type memory, a random-access memory (RAM), a static RAM (SRAM), a read-only memory (ROM), an electrically erasable programmable ROM (EEPROM), a programmable ROM (PROM), a magnetic memory, a magnetic disk, and an optical disk.

The centering jig 226 has been briefly described so far and will hereinafter be described in further detail.

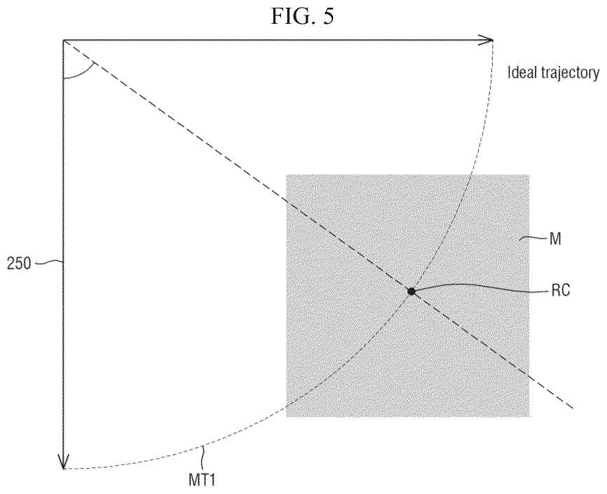

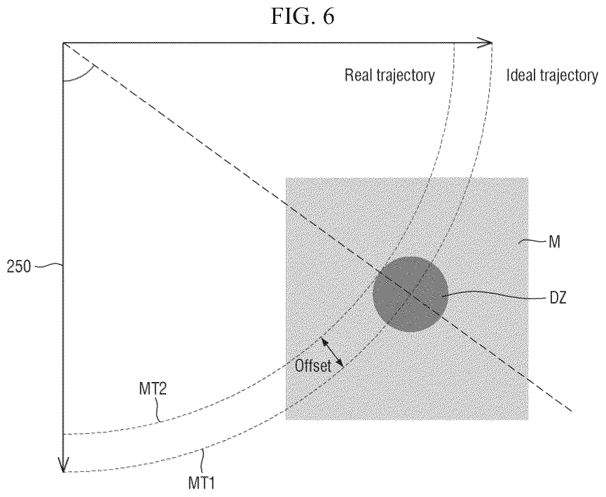

Referring to FIG. 5, for the beam irradiation module 252 to target all points on a mask M, the swing arm 250 may have an ideal movement trajectory MT1 that passes through a rotation center RC of the spin chuck 221. However, if the swing arm 250 actually has a moving trajectory MT2 that does not pass through the rotation center RC of the spin chuck 221, as illustrated in FIG. 6, the beam irradiation module 252 cannot target all points on the mask M. In this case, a physically untargetable dead zone DZ may occur on the mask M.

To address this problem, the centering jig 226 may be utilized to enable the movement trajectory of the swing arm 250 to pass through the rotation center of the spin chuck 221. FIG. 5 is a first example schematic diagram for explaining the role of the centering jig in the substrate processing apparatus. FIG. 6 is a second example schematic diagram for explaining the role of the centering jig in the substrate processing apparatus.

The centering jig 226 may be used to measure and correct the degree of misalignment of the movement trajectory of the swing arm 250 relative to the rotation center of the spin chuck 221. The centering jig 226 may serve as a measurement base for such measurement and correction. The centering jig 226 may be fabricated to be able to be assembled to the spin chuck 221. The centering jig 226 may be attached to the center of the spin chuck 221.

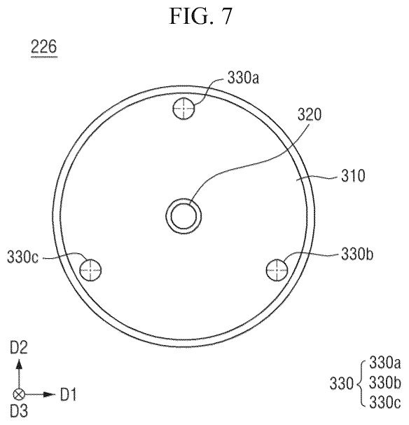

Referring to FIG. 7, the centering jig 226 may include a first hole 320 and second holes 330, and the first hole 320 and the second holes 330 may penetrate a body 310 of the centering jig 226 in the third direction D3. The body 310 may be formed as a cylinder, but embodiments of the present disclosure are not limited thereto. Alternatively, the body 310 may be formed in various other shapes, such as a polygonal prism or an elliptical cylinder.

The first hole 320 may be used to align the movement trajectory of the swing arm 250 with the rotation center of the spin chuck 221. The centering jig 226 may be installed on the spin chuck 221 so that the first hole 320 coincides with the rotation center of the spin chuck 221. A single first hole 320 may be formed in the center of the body 310. To enable the image acquisition module 251 to stably acquire a surface image of the spin chuck 221 through the first hole 320, the first hole 320 may have a sufficient diameter. For example, the first hole 320 may have a diameter that ranges from, for example, tens to hundreds of micrometers (μm).

The second holes 330 may be used to fix the centering jig 226 to the spin chuck 221. A plurality of second holes 330 may be formed at the edge of the body 310. For example, three second holes 330a, 330b, and 330c may be formed at the edge of the body 310.

Fixing members may be inserted into the second holes 330. The fixing members may fasten the centering jig 226 to the spin chuck 221. The level of the centering jig 226 on the spin chuck 221 may be adjusted. Here, the term “level” refers to the height from the surface of the spin chuck 221. The fixing members may be used to adjust the level of the centering jig 226 on the spin chuck 221. The level of the centering jig 226 may be adjusted when aligning the movement trajectory of the swing arm 250 with the rotation center of the spin chuck 221. For example, the fixing members may be provided as set screws. FIG. 7 is a plan view for explaining the structure of a centering jig according to a first embodiment of the present disclosure.

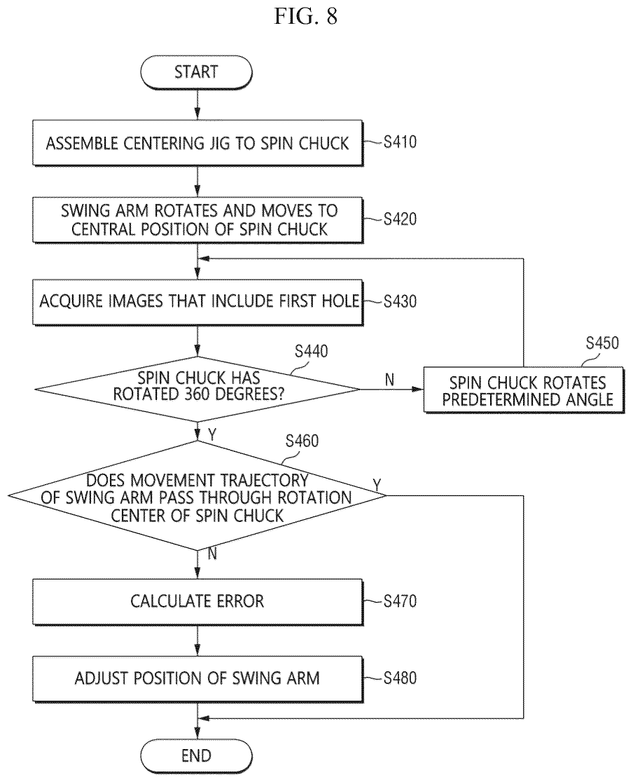

It will hereinafter be described how to align the movement trajectory of the swing arm 250 with the rotation center of the spin chuck 221 using the centering jig 226. FIG. 8 is a flowchart for explaining a method of aligning the movement trajectory of the swing arm with the rotation center of the spin chuck.

The method of FIG. 8 may be performed in an equipment setup phase or preventive maintenance (PM) phase. The method of FIG. 8 may be performed using the centering jig 226. The method of FIG. 8 may be performed to prevent the occurrence of the dead zone DZ on the mask M.

Referring to FIG. 8, the centering jig 226, which has the first hole 320 formed at its center, is assembled onto the spin chuck 221 (operation S410). The centering jig 226 may be installed at the center of the spin chuck 221. The centering jig 226 may be installed on the spin chuck 221 to ensure that the first hole 320 is positioned at the rotation center of the spin chuck 221.

Thereafter, the swing arm 250 is rotated and moved to the central position of the spin chuck 221 (operation S420). The central position of the spin chuck 221 may be already known based on the design of the substrate processing apparatus 100, and the rotation angle of the swing arm 250 may also be determined in advance.

Thereafter, images that include the first hole 320 may be acquired (operation S430) by photographing the spin chuck 221 using the image acquisition module 251. If the center of the first hole 320 coincides exactly with the rotation center of the spin chuck 221, a determination may be made only as to whether the center of the first hole 320 in a captured image is aligned with the vision center of the camera sensor 251a. However, due to manufacturing and assembly tolerances, there may be an offset between the center of the first hole 320 and the rotation center of the spin chuck 221. Therefore, to properly locate the actual rotation center of the spin chuck 221, the spin chuck 221 may be rotated and multiple images may be captured during such time.

The image acquisition module 251 may acquire multiple images while rotating the spin chuck 221 360 degrees. In this case, the process of rotating the spin chuck 221 a predetermined angle and then capturing a single image via the image acquisition module 251 may be repeated multiple times (the operation S430, the operation S440, the operation S450). The spin chuck 221 may be rotated either clockwise or counterclockwise.

For example, the spin chuck 221 may be rotated 60 degrees clockwise, and the image acquisition module 251 may capture a first image. Then, the spin chuck 221 may be rotated another 60 degrees clockwise, and the image acquisition module 251 may acquire a second image. In this manner, the image acquisition module 251 may acquire six images that all include the first hole 320, while rotating the spin chuck 221 360 degrees. To eliminate errors that may be caused by assembly tolerances, a minimum of six images that include the first hole 320 may be acquired by rotating the spin chuck 221 in intervals of 60 degrees.

Thereafter, the control unit 140 processes the multiple images and determines whether the movement trajectory of the swing arm 250 passes through the rotation center of the spin chuck 221 based on the results of the processing (operation S460).

If it is determined that the movement trajectory of the swing arm 250 does not pass through, but deviates from the rotation center of the spin chuck 221, the control unit 140 calculates the error indicating how far the movement trajectory of the swing arm 250 deviates from the rotation center (operation S470).

Thereafter, the position of the swing arm 250 is adjusted based on the calculated error (operation S480). The position of the swing arm 250 may be adjusted to align centering between the movement trajectory of the swing arm 250 and the rotation center of the spin chuck 221. Specifically, the swing arm 250 may be detached from a stage fixing part of the chamber housing 210 and may be finely adjusted using a micrometer.

Once the position of the swing arm 250 is adjusted, images are reacquired (e.g., the operation S430, the operation S440, and the operation S450 may be repeated), and a determination is made again as to whether the movement trajectory of the swing arm 250 passes through the rotation center of the spin chuck 221 (the operation S460). The process of reacquiring images and making such determination based on the reacquired images may be repeated until it is determined that the movement trajectory of the swing arm 250 passes through the rotation center of the spin chuck 221.

Even if there is an error between the movement trajectory of the swing arm 250 with the rotation center of the spin chuck 221, the control unit 140 may not align the movement trajectory of the swing arm 250 with the rotation center of the spin chuck 221, provided the error is deemed to be negligibly small. For example, the control unit 140 may decide not to align the movement trajectory of the swing arm 250 with the rotation center of the spin chuck 221 if the error is determined to be less than 5 micrometers.

The control unit 140 compares the error, indicating how far the movement trajectory of the swing arm 250 deviates from the rotation center of the spin chuck 221, with a reference value. If the error is equal to or smaller than the reference value, the control unit 140 does not align the movement trajectory of the swing arm 250 with the rotation center of the spin chuck 221. Conversely, if the error is greater than the reference value, the control unit or a person may 140 finely adjust the position of the swing arm 250. Then, the process of reacquiring images and determining whether the movement trajectory of the swing arm 250 passes through the rotation center of the spin chuck 221 based on the reacquired images may be performed again to align the movement trajectory of the swing arm 250 with the rotation center of the spin chuck 221.

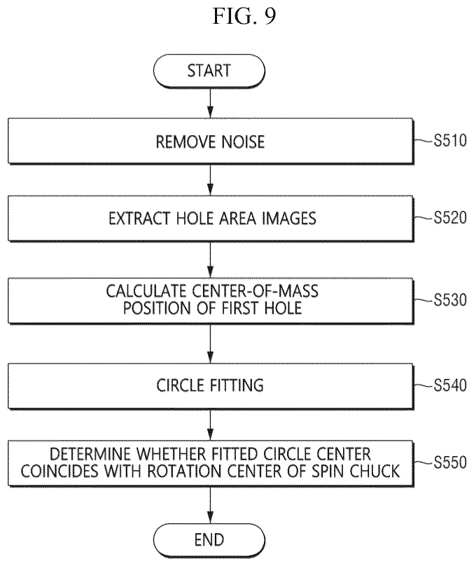

As previously explained, the control unit 140 may determine whether the movement trajectory of the swing arm 250 passes through the rotation center of the spin chuck 221 by processing multiple images that include the first hole 320 of the centering jig 226. An example where the image acquisition module 251 acquires first through sixth images while rotating the spin chuck 221 360 degrees, and the control unit 140 processes the first through sixth images will hereinafter be described. FIG. 9 is a flowchart for explaining a method of processing multiple images.

Referring to FIG. 9, the control unit 140 removes noise from each of the first through sixth images (operation S510). The control unit 140 may use a morphological processing technique to remove noise from each of the first through sixth images. For example, the control unit 140 may use operations such as erosion and dilation to remove noise from each of the first through sixth images.

Thereafter, the control unit 140 processes the noise-removed images to extract hole area images (operation S520). The hole area images may include contours related to the first hole 320, and the size of the first hole 320 in the hole area images may be enlarged compared to that in the noise-removed images. The number of hole area images may be the same as the number of noise-removed images, but embodiments of the present disclosure are not limited thereto.

The control unit 140 may extract hole area images that clearly show the first hole 32. The control unit 140 may rescale the noise-removed images, set a threshold, perform image binarization, and extract the hole area images. The control unit 140 may perform rescale based on the overall brightness. For example, the control unit 140 may perform a colorbar rescale. The control unit 140 may perform image binarization and/or a thresholding method, such as Otsu's method.

Thereafter, the control unit 140 calculates the center-of-mass position of the first hole 320 from each the hole area images (operation S530). The control unit 140 may extract binarized hole contours from each of the hole area images and may calculate the center-of-mass position of the first hole 320 based on the extracted contours. The control unit 140 may set the center-of-mass position of the first hole 320 as the position of a hole center.

The control unit 140 may calculate a center offset based on the center of each of the hole area images and the center-of-mass position of the first hole 320 within the corresponding hole area image. The center offset indicates how far the center-of-mass position of the first hole 320 is from the center of the corresponding hole area image. Then, the control unit 140 may correct the center-of-mass position of the first hole 320 based on the center offset.

The operation S510, the operation S520, and the operation S530 may involve simultaneously processing the first through sixth images to calculate the center-of-mass position of the first hole 320 in each of the processed images, but embodiments of the present disclosure are not limited thereto. Alternatively, the first through sixth images may be sequentially processed to calculate the center-of-mass position of the first hole 320 in each of the processed images.

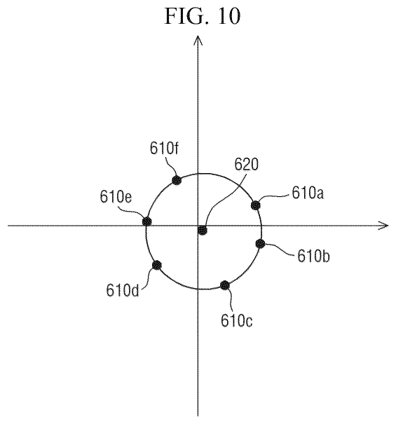

Thereafter, the control unit 140 determines whether the movement trajectory of the swing arm 250 passes through the rotation center of the spin chuck 221 based on the center-of-mass position of the first hole 320 (operation S540 and operation S550). Specifically, referring to FIG. 10, the control unit 140 may perform circle fitting based on the positions of hole centers 610a, 610b, 610c, 610d, 610e, and 610f (operation S540) and determine whether a fitted circle center 620 obtained by the circle fitting coincides with the rotation center of the spin chuck 221 (S550). FIG. 10 is an example schematic diagram for explaining circle fitting as performed in the method of FIG. 9.

If the fitted circle center 620 coincides with the rotation center of the spin chuck 221, the control unit 140 may determine that the movement trajectory of the swing arm 250 passes through the rotation center of the spin chuck 221. Conversely, if the fitted circle center 620 does not coincide with the rotation center of the spin chuck 221, the control unit 140 may determine that the movement trajectory of the swing arm 250 does not pass through the rotation center of the spin chuck 221.

If it is determined that the movement trajectory of the swing arm 250 deviates from the rotation center of the spin chuck 221, the control unit 140 may calculate the error. The control unit 140 may calculate the error based on how far the circle center obtained through circle fitting is from the center of the corresponding image. The calculated error may be the distance between the circle center obtained through circle fitting and the center of the corresponding image, which may be the vision center of the camera sensor 251a.

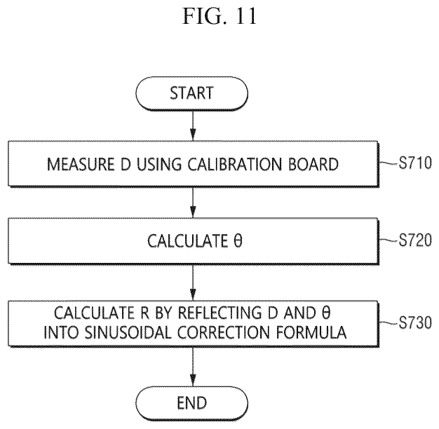

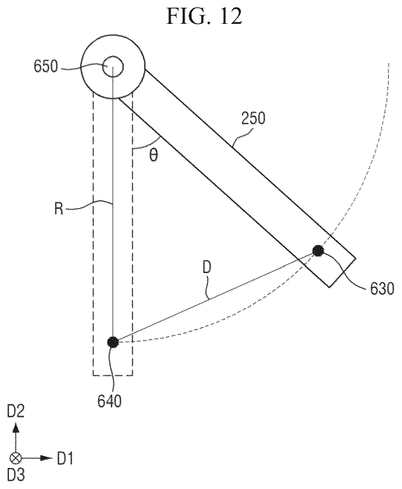

When adjusting the position of the swing arm 250, knowing the length of the swing arm 250 may allow for a more precise centering between the movement trajectory of the swing arm 250 and the rotation center of the spin chuck 221. The length of the swing arm 250 may be measured using a calibration board. FIG. 11 is a flowchart for explaining a method of measuring the length of the swing arm. FIG. 12 is an example schematic diagram for explaining the method of FIG. 11. According to embodiments of the present disclosure, the control unit 140 may perform the method of FIG. 11.

Referring to FIGS. 11 and 12, a value D is measured using a calibration board (operation S710). The value D may be calculated using the following Equation 1:

$$D = Center Measurement Value - Home Measurement Value \qquad ( Equation 1 )$$

The center measurement value refers to the coordinates of the light inlet 256 of the swing arm 250 when the light inlet 256 is located at the rotation center 630 of the spin chuck 221. The coordinates of the light inlet 256 may be represented as (θ, φ) based on the θ/φ coordinate system, but embodiments of the present disclosure are not limited thereto. Alternatively, the coordinates of the light inlet 256 may be represented as (X, Y) based on an X/Y coordinate system. The θ/φ coordinate system may be obtained using a rotational angle θ of the swing arm 250 and a rotation angle φ of the spin chuck 221.

The home measurement value refers to the coordinates of the light inlet 256 when the light inlet 256 is located at a home point 640. When the light inlet 256 is at the home point 640, the length direction of the swing arm 250 may be parallel to the second direction D2. The value D may be the straight-line distance between the position of the light inlet 256 at the rotation center of the spin chuck 221 and the position of the light inlet 256 at the home point 640.

Thereafter, the rotation angle θ of the swing arm 250 is calculated (operation S720). The rotation angle θ of the swing arm 250 may be calculated using the following Equation 2:

$$( Equation 2 )$$

$$θ = ( Center Measurement Value - Home Measurement Value ) * Angle per Pulse$$

Coordinates relative to a rotation axis 650 of the swing arm 250 may be calculated using the θ/φ coordinate system. The rotation angle θ of the swing arm 250 may also be calculated using the coordinates of the light inlet 256 at the rotation center of the spin chuck 221 or at the home point 640 and the coordinates of the rotation axis 650.

Thereafter, a length R of the swing arm 250 is calculated by reflecting the value D and the rotation angle θ into a sinusoidal correction formula (operation S730). Here, the length R of the swing arm 250 may be the distance between the rotation axis 650 and the light inlet 256.

As previously described with reference to FIG. 7, the centering jig 226 may be provided as a structure that is assembled onto the spin chuck 221, but embodiments of the present disclosure are not limited thereto. Alternatively, the centering jig 226 may be provided as a substrate-shaped structure that can be mounted on the spin chuck 221. For example, the centering jig 226 may be provided as a dummy substrate. The dummy substrate may include patterns for use in aligning the movement trajectory of the swing arm 250 with the rotation center of the spin chuck 221. This will hereinafter be described.

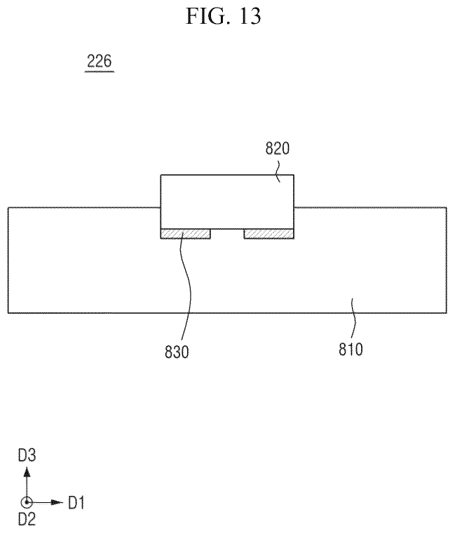

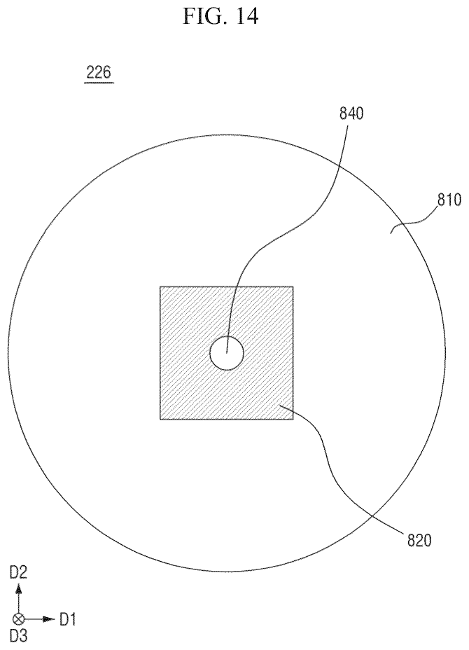

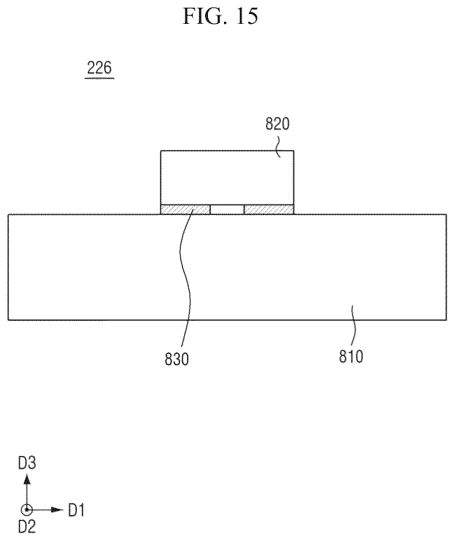

FIG. 13 is a side view for explaining the structure of a centering jig according to a second embodiment of the present disclosure. FIG. 14 is a plan view for explaining the structure of the centering jig according to the second embodiment of the present disclosure. FIG. 15 is a side view for explaining the structure of a centering jig according to a third embodiment of the present disclosure. Referring to FIGS. 13 through 15, a centering jig 226 may include a first body 810, a second body 820, and a coating layer 830.

The first body 810 may be provided as a substrate-shaped structure. For example, the first body 810 may be provided as a disk-shaped structure with a circular cross-sectional shape. When aligning the movement trajectory of the swing arm 250 with the rotation center of the spin chuck 221, the centering jig 226 may be supported by the support pins 224 and the guide pins 225 (refer to FIG. 2).

The second body 820 may be coupled to the first body 810. The first abody 810 and the second body 820 may be bonded together or may be coupled using fixing members such as set screws. The second body 820 may form a groove on the first body 810 and may be coupled to the first body 810 through the groove, but embodiments of the present disclosure are not limited thereto. Alternatively, the second body 820 may be coupled on the plane of the first body 810.

The second body 820 may have a different shape from a shape of the first body 810. For example, the second body 820 may be a rectangular column-shaped structure with a rectangular cross-sectional shape, but embodiments of the present disclosure are not limited thereto. Alternatively, the second body 820 may have the same shape as a shape of the first body 810.

The coating layer 830 may be formed on the bottom surface of the second body 820. As the first body 810 and the second body 820 are coupled together, the coating layer 830 may be covered by the first body 810 and the second body 820. The coating layer 830 may be protected from the outside by the first body 810 and the second body 820.

The coating layer 830 may be formed of a metal. For example, the coating layer 830 may be formed of chromium (Cr). The coating layer 830 may also be formed of other metals or materials as long as it can be easily distinguished from a pattern 840.

The pattern 840 may be formed to be surrounded by the coating layer 830. The pattern 840 may be circular, but embodiments of the present disclosure are not limited thereto. The pattern 840 may perform the same role as the first hole 320 of FIG. 7. That is, the pattern 840 may be used to align the movement trajectory of the swing arm 250 with the rotation center of the spin chuck 221.

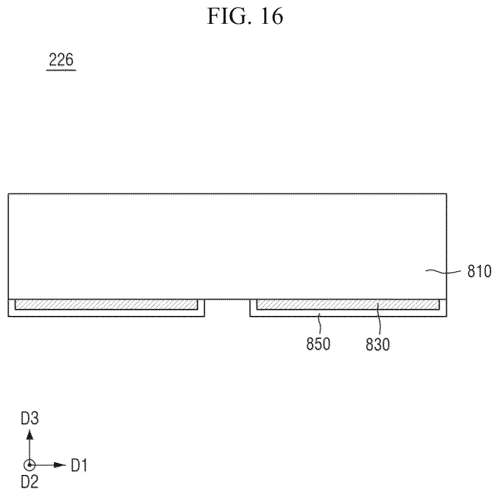

The structure of a centering jig 226 including multiple bodies has been described so far. However, embodiments of the present disclosure are not limited to this, and alternatively, the centering jig 226 may be configured to include a single body. Referring to FIGS. 16, the centering jig 226 may be configured to include a first body 810 and a coating layer 830. FIG. 16 is a side view for explaining the structure of a centering jig according to a fourth embodiment of the present disclosure.

The coating layer 830 may be formed on the bottom surface of the first body 810. Like in the embodiments of FIGS. 13 through 15, a pattern 840 may be formed to be surrounded by the coating layer 830. As the coating layer 830 is formed on the surface of the first body 810, the coating layer 830 may not be protected from the outside. To address this issue, the centering jig 226 may further include a protective layer 850. The protective layer 850 may generally cover the coating layer 830. The protective layer 850 may be formed of the same material as a material of the coating layer 830, but embodiments of the present disclosure are not limited thereto.

The alignment of the movement trajectory of the swing arm 250 with the rotation center of the spin chuck 221 using the centering jig 226 of FIGS. 13 through 16 may be performed in the same manner as the alignment of the movement trajectory of the swing arm 250 with the rotation center of the spin chuck 221 using the centering jig 226 of FIG. 7. Instead of assembling a centering jig 226 with a first hole 320 onto the spin chuck 221, a centering jig 226 with a pattern 840, which serves the same purpose as the first hole 320, may be mounted on the spin chuck 221. According to embodiments of the present disclosure, the methods of FIGS. 8-9 and 11 may be performed with respect to a substrate processing apparatus (e.g., substrate processing apparatus 100) that includes the centering jig 226 of FIGS. 13-16, wherein the “first hole” described with respect to the operations of such methods is replaced with the “pattern” (e.g., the pattern 840).

Embodiments of the present disclosure may be applied to wet etching equipment, wet cleaning equipment, etc. Embodiments of the present disclosure may be applied to, but is not limited to, using a laser device to precisely target points on a mask within such equipment. That is, embodiments of the present disclosure can also be applied to any equipment that includes a swing arm and a rotation chuck.

Non-limiting example embodiments of the present disclosure have been described above with reference to the accompanying drawings, but embodiments of the present disclosure are not limited thereto and may be implemented in various different forms. It will be understood that embodiments of the present disclosure can be implemented in other specific forms without departing from the scope of the present disclosure. Therefore, it should be understood that the example embodiments set forth herein are illustrative in all respects and not limiting.

What is claimed is:

1. A substrate processing apparatus comprising:
a support unit comprising a spin chuck and a centering jig that is on the spin chuck, the spin chuck configured to support and rotate a substrate;
a spraying unit configured to spray processing liquid onto the substrate;
a swing arm comprising a correction unit that comprises a sensor and an emitter, the swing arm configured to move such that the correction unit moves to a target point on the substrate, and the emitter configured to irradiate a beam towards the substrate; and
a controller configured to:
control the spin chuck and the swing arm; and
determine whether a movement trajectory of the swing arm is aligned with a rotation center of the spin chuck based on information acquired by the sensor about the centering jig.

2. The substrate processing apparatus of claim 1, wherein the centering jig comprises a body, a first hole at a center of the body, and a plurality of second holes at an edge of the body,
wherein the centering jig is fastened to the spin chuck via the plurality of second holes, and
wherein the first hole is at the rotation center of the spin chuck.

3. The substrate processing apparatus of claim 1, wherein the centering jig is configured to be adjusted such that a level of the centering jig from a surface of the spin chuck is adjustable.

4. The substrate processing apparatus of claim 1, wherein the controller is further configured to process a plurality of images obtained by the sensor, and determine whether the movement trajectory of the swing arm is aligned with the rotation center of the spin chuck based on a result of the processing.

5. The substrate processing apparatus of claim 4, wherein the controller is further configured to control the correction unit to acquire the plurality of images while rotating the spin chuck to predetermined angles.

6. The substrate processing apparatus of claim 5, wherein the controller is further configured to control the correction unit to acquire the plurality of images while rotating the spin chuck 360 degrees.

7. The substrate processing apparatus of claim 4, wherein the controller is further configured to determine whether the movement trajectory of the swing arm passes through the rotation center of the spin chuck based on a result of the processing.

8. The substrate processing apparatus of claim 1, wherein the controller is further configured to calculate an error between the movement trajectory of the swing arm and the rotation center of the spin chuck.

9. The substrate processing apparatus of claim 8, wherein the swing arm is configured to be adjusted to compensate for the error.

10. The substrate processing apparatus of claim 9, wherein a position of the swing arm is configured to be adjusted using a micrometer after detaching the swing arm from the substrate processing apparatus.

11. The substrate processing apparatus of claim 4, wherein the controller is further configured to:
calculate a center-of-mass position of a first hole in each of the plurality of images; and
perform circle fitting on the center-of-mass position of the first hole to produce a result of the processing.

12. The substrate processing apparatus of claim 11, wherein the controller is further configured to:
rescale each of the plurality of images based on brightness,
extracting enlarged images of the first hole by binarizing the images, that are rescaled, using a threshold, and
calculate the center-of-mass position of the first hole based on the enlarged images that are extracted.

13. The substrate processing apparatus of claim 11, wherein the controller is further configured to determine whether the movement trajectory of the swing arm passes through the rotation center of the spin chuck based on whether a center of a fitted circle matches a center of each of the plurality of images, and
wherein the center of each of the images is a vision center of the sensor.

14. The substrate processing apparatus of claim 1, wherein the swing arm is configured to be adjusted such that the movement trajectory of the swing arm becomes aligned with the rotation center of the spin chuck.

15. The substrate processing apparatus of claim 14, wherein the controller is further configured to adjust a position of the swing arm based on a length of the swing arm.

16. The substrate processing apparatus of claim 15, wherein the controller is further configured to calculate the length of the swing arm based on a distance between a first coordinate and a second coordinate, and a rotational angle of the swing arm from the first coordinate to the second coordinate.

17. The substrate processing apparatus of claim 16, wherein the first coordinate is at a home position of the swing arm, and
wherein the second coordinate is at the rotation center of the spin chuck.

18. The substrate processing apparatus of claim 1, wherein the centering jig comprises a first body, a second body coupled to the first body, a coating layer on a bottom surface of the second body, and a pattern surrounded by the coating layer, and
wherein the controller is further configured to determine whether the movement trajectory of the swing arm is aligned with the rotation center of the spin chuck based on the pattern.

19. A control device comprising:
a controller configured to:
control a spin chuck, that is configured to support and rotate a substrate, and a swing arm, that is configured to move to a target point on the substrate and irradiate a beam for processing the substrate; and
determine whether a movement trajectory of the swing arm is aligned with a rotation center of the spin chuck by processing a plurality of images obtained by the swing arm, the plurality of images including a first hole of a centering jig at the rotation center of the spin chuck,
wherein the centering jig is on the spin chuck.

20. A substrate processing apparatus comprising:
a support unit comprising a spin chuck and a centering jig that is on the spin chuck, the spin chuck configured to support and rotate a substrate;
a spraying unit configured to spray processing fluid onto the substrate;
a swing arm comprising a correction unit that comprises a sensor and an emitter, the swing arm configured to move such that the correction unit moves to a target point on the substrate, and the correction unit configured to irradiate a beam, via the emitter, towards the substrate and acquire a plurality of images, via the sensor, while the spin chuck is rotated a predetermined angle; and
a controller configured to:
control the spin chuck and the swing arm;
rescale each of the plurality of images based on brightness;
extract enlarged images of a first hole by binarizing the plurality of images, that are rescaled, using a threshold;
calculate a center-of-mass position of the first hole from each of the enlarged images that are extracted;
perform circle fitting on the center-of-mass position of the first hole; and
determine whether a movement trajectory of the swing arm passes through a rotation center of the spin chuck based on a result of the circle fitting.
